(19) United States
(12) Patent Application Publication
(10) Pub. No.: US 2015/0108468 A1
(43) Pub. Date: Apr. 23, 2015

(54) THIN FILM TRANSISTOR AND METHOD OF MANUFACTURING THE SAME

(71) Applicant: SAMSUNG DISPLAY CO., LTD., Yongin-City (KR)

(72) Inventors: Jun Hyuk CHEON, Seoul (KR); Mu Gyeom KIM, Hwaseong-si (KR)

(21) Appl. No.: 14/468,601

(22) Filed: Aug. 26, 2014

(30) Foreign Application Priority Data
Oct. 21, 2013 (JP) 10-2013-0125424

(51) Int. Cl. H01L 29/786; H01L 21/02; H01L 29/417; H01L 29/66; H01L 29/423

(52) U.S. Cl. CPC H01L 29/7869; H01L 29/66969; H01L 29/42384; H01L 29/41733; H01L 21/02667; H01L 21/02675; H01L 2029/42388
USPC 257/43; 438/104

(57) ABSTRACT

A thin film transistor may include a substrate, an oxide semiconductor layer on the substrate, a first insulating layer on the oxide semiconductor layer, a gate electrode on the first insulating layer, a second insulating layer on the gate electrode, and a source electrode and a drain electrode on the second insulating layer and facing each other. Each of the source electrode and the drain electrode may be connected with the oxide semiconductor layer through a contact hole in the second insulating layer. The oxide semiconductor layer may include a polycrystalline semiconductor.

### CROSS-REFERENCE TO RELATED APPLICATION

The present application claims priority under 35 U.S.C. §119 to Korean Patent Application No. 10-2013-0125424, filed on Oct. 21, 2013, in the Korean Intellectual Property Office, and entitled: “Thin Film Transistor And Method Of Manufacturing The Same,” which is incorporated by reference herein in its entirety.

### BACKGROUND

1. Field

Embodiments relate to a thin film transistor and a manufacturing method thereof.

2. Description of the Related Art

A flat panel display, such as a liquid crystal display (LCD), an organic light emitting diode (OLED) display, and an electrophoretic display, and a plasma display, may include a plurality of pairs of field generating electrodes, and electro-optical active layers therebetween. The LCD may include a liquid crystal layer as the electro-optical active layer, and the OLED display may include an organic emission layer as the electro-optical active layer. One of the field generating electrodes, which make a pair, may be generally connected to a switching element to receive an electric signal. The electro-optical active layer may convert the electric signal into an optical signal to display an image. In the flat panel display, a display panel with a thin film transistor may be included. On a thin film transistor array panel, electrodes of many layers, a semiconductor, and the like are patterned, and generally, a mask may be used during a patterning process.

### SUMMARY

Embodiments are directed to a thin film transistor, which may include a substrate, an oxide semiconductor layer on the substrate, a first insulating layer on the oxide semiconductor layer, a gate electrode on the first insulating layer, a second insulating layer on the gate electrode, and a source electrode and a drain electrode on the second insulating layer and facing each other. Each of the source electrode and the drain electrode may be connected with the oxide semiconductor layer through a contact hole in the second insulating layer. The oxide semiconductor layer may include a polycrystalline semiconductor.

Edge boundaries of the first insulating layer and the gate electrode may coincide with each other. The second insulating layer may entirely or partially cover a side of the first insulating layer and a side of the gate electrode. The thin film transistor may further include a buffer layer between the substrate and the oxide semiconductor layer. One edge of each of the source electrode and the drain electrode may overlap with the gate electrode. The contact hole may be formed in the first insulating layer and the second insulating layer. The thin film transistor may further include a buffer layer between the substrate and the oxide semiconductor layer. One edge of each of the source electrode and the drain electrode may overlap with the gate electrode.

A manufacturing method of a thin film transistor is provided that may include the following. An oxide semiconductor layer may be formed on a substrate. A light irradiation or heat treatment may be performed on the oxide semiconductor layer. An insulating material layer and a gate electrode material layer may be formed on the oxide semiconductor layer. A gate electrode may be formed by patterning the gate electrode material layer. An interlayer insulating layer may be formed on the gate electrode. A source electrode and a drain electrode may be formed on the interlayer insulating layer. Each of the source electrode and the drain electrode may be connected with the oxide semiconductor layer through a contact hole in the interlayer insulating layer. The oxide semiconductor layer may include a polycrystalline semiconductor.

The manufacturing method of a thin film transistor may further include one or more additional steps. A capping layer may be formed on the oxide semiconductor layer before performing light irradiation or heat treatment on the oxide semiconductor layer. The capping layer may be removed after performing light irradiation or heat treatment on the oxide semiconductor layer. A process temperature for performing light irradiation or heat treatment on the oxide semiconductor layer may be from about 400° C. to about 500° C. or less. An insulating layer may be formed by patterning the insulating material layer by using the gate electrode as a mask. The interlayer insulating layer may be formed entirely or partially cover a side of the insulating layer and a side of the gate electrode. A buffer layer may be formed between the substrate and the oxide semiconductor layer. One edge of each of the source electrode and the drain electrode may be formed to overlap with the gate electrode. The contact hole may be formed in the insulating material layer and the interlayer insulating layer. A buffer layer may be between the substrate and the oxide semiconductor layer containing such a hole. One edge of each of the source electrode and the drain electrode may be formed to overlap with the gate electrode.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a thin film transistor.

FIGS. 2 to 9 illustrate cross-sectional views of a manufacturing method of a thin film transistor.

FIG. 10 illustrates a cross-sectional view of a thin film transistor.

FIG. 11 illustrates a graph of a characteristic of the thin film transistor manufactured according to a method described herein.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawings, the thickness and/or other dimensions of layers, films, panels, regions, or the like, may be exaggerated for clarity. When a layer is referred to as being “on” another layer or substrate, it can be directly on the other layer or substrate, or an intervening layer may be present. Like reference numerals designate like elements throughout the specification.

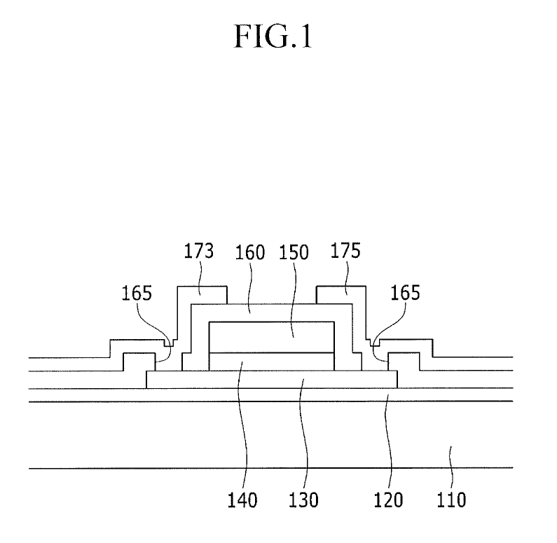

FIG. 1 illustrates a cross-sectional view of a thin film transistor. Referring to FIG. 1, a buffer layer 120 may be on an insulation substrate 110, which may include glass, plastic, or the like. The buffer layer 120 may include an insulating material such as silicon oxide (SiO₂), silicon nitride (SiNₓ), and silicon oxynitride. In FIG. 1, the buffer layer 120 is illustrated as a single layer, but may be formed as a multilayer. The buffer layer 120 may prevent an impurity from flowing into a semiconductor to be laminated later from the insulation substrate 110 to protect the semiconductor and improve an interface characteristic of the semiconductor.

An oxide semiconductor layer 130 may be on the buffer layer 120. The oxide semiconductor layer 130 may include a metal oxide semiconductor, including, for example, an oxide of a metal such as zinc (Zn), indium (In), gallium (Ga), tin (Sn), and/or titanium (Ti) or a combination of two or more metals such as zinc (Zn), indium (In), gallium (Ga), tin (Sn), and titanium (Ti), and/or an oxide thereof. For example, an oxide semiconductor material may include at least one of a zinc oxide (ZnO), a zinc-tin oxide (ZTO), a zinc-indium oxide (ZIO), an indium oxide (InO), a titanium oxide (TiO), an indium-gallium-zinc oxide (IGZO), and an indium-zinc-tin oxide (IZTO). The oxide semiconductor layer 130 may include a crystalline semiconductor. The oxide semiconductor layer 130 may be crystallized by laser or heat treatment and may include a crystal structure such as monocrystalline or polycrystalline.

A first insulating layer 140 may be on the oxide semiconductor layer 130. The first insulating layer 140 may be a single layer or a multilayer of a double layer or more. Where the first insulating layer 140 is the single layer, for example, the first insulating layer 140 may include an insulating oxide such as silicon oxide (SiO₂), aluminum oxide (Al₂O₃), hafnium oxide (HfO₃), and/or yttrium oxide (Y₂O₃). The first insulating layer 140 may improve the interface characteristic of the oxide semiconductor layer 130 and may prevent an impurity from penetrating into the oxide semiconductor layer 130.

A gate electrode 150 may be on the first insulating layer 140. An edge boundary of the gate electrode 150 and an edge boundary of the first insulating layer 140 may substantially coincide with each other to be arranged. The gate electrode 150 may include a portion overlapping with the oxide semiconductor layer 130, and the oxide semiconductor layer 130 may be covered by the gate electrode 150. The gate electrode 150 may include, for example, a metal such as aluminum (Al), silver (Ag), copper (Cu), molybdenum (Mo), chromium (Cr), tantalum (Ta), or titanium (Ti), or a combination thereof, and/or an alloy thereof. The gate electrode 150 may have a structure of a single layer or a multilayer. For example, the multilayer may include a double layer of a lower layer of titanium (Ti), tantalum (Ta), molybdenum (Mo), ITO, or the like and an upper layer of copper (Cu) or the like, a triple layer of molybdenum (Mo)-aluminum (Al)-molybdenum (Mo), or the like. However, the gate electrode 150 may include various metals or conductors in addition to or as an alternative to such metals.

A second insulating layer 160 may be on the gate electrode 150, the oxide semiconductor layer 130, and the buffer layer 120. The second insulating layer 160 may include an inorganic insulating material such as silicon nitride or silicon oxide, an organic insulating material, a combination thereof, or the like. A contact hole 165 exposing a source electrode 173 and a drain electrode 175 may be in the second insulating layer 160. The source electrode 173 and the drain electrode 175 may be on the second insulating layer 160 spaced apart from each other. The source electrode 173 and the drain electrode 175 may be electrically connected with the oxide semiconductor layer 130 through the contact hole 165 in the second insulating layer 160, respectively.

As illustrated in FIG. 1, for example, one edge of the source electrode 173 may overlap with the gate electrode 150, and one edge of the drain electrode 175 may overlap with the gate electrode 150. The source electrode 173 and the drain electrode 175 may be formed so as not to substantially overlap with the gate electrode 150. The gate electrode 150, the source electrode 173, and the drain electrode 175 may form a thin film transistor (TFT) together with the oxide semiconductor layer 130, and a channel of the thin film transistor may be formed in the oxide semiconductor layer 130.

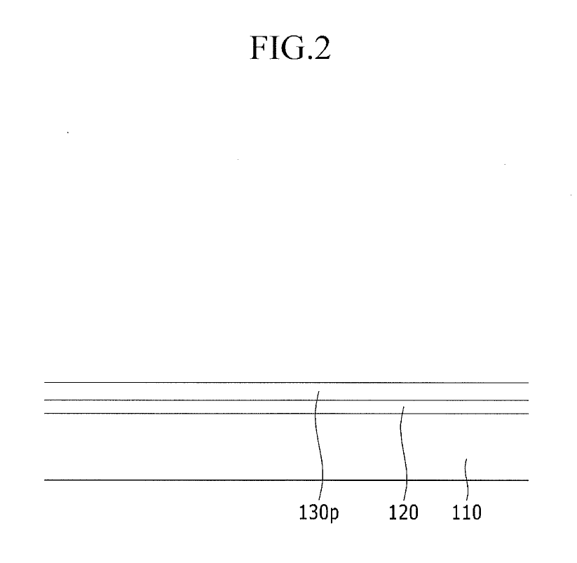

A manufacturing method for manufacturing the thin film transistor illustrated in FIG. 1 is described with reference to FIGS. 2 to 9 in addition to FIG. 1 described herein. FIGS. 2 to 9 illustrate cross-sectional views of a manufacturing method of a thin film transistor. Referring to FIG. 2, on an insulation substrate 110, which may include glass, plastic, or the like, a buffer layer 120, which may include insulating material such as silicon oxide (SiO₂), silicon nitride (SiNₓ), and/or silicon oxynitride, may be formed by a chemical vapor deposition (CVD) method or the like. An oxide semiconductor material layer 130p, which may include an oxide semiconductor material such as a zinc oxide (ZnO), a zinc-tin oxide (ZTO), a zinc-indium oxide (ZIO), an indium oxide (InO), a titanium oxide (TiO), an indium-gallium-zinc oxide (IGZO), and/or an indium-zinc-tin oxide (IZTO), may be coated on the buffer layer 120, for example, by using a sputtering method or the like. The oxide semiconductor material layer 130p may be in an amorphous state.

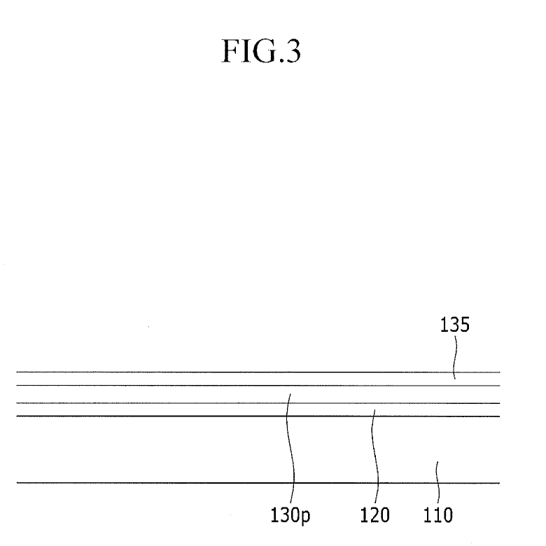

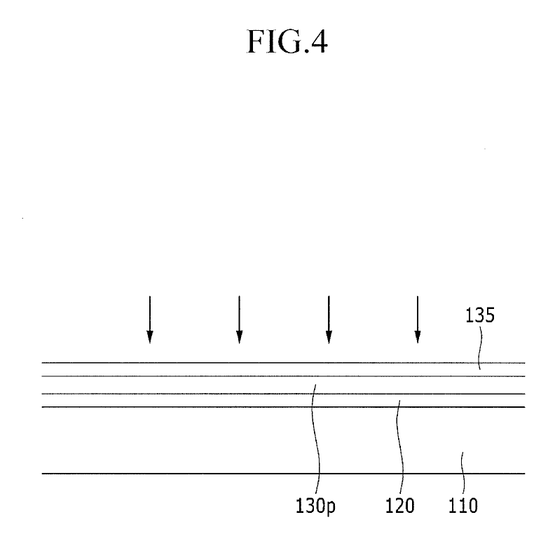

Referring to FIG. 3, a capping layer 135 may be coated on the oxide semiconductor material layer 130p. The capping layer 135 may include an insulating material such as silicon oxide (SiO₂), silicon nitride (SiNₓ), and silicon oxynitride. Referring to FIG. 4, as illustrated by an arrow, a laser may be irradiated toward the capping layer 135 to crystallize the oxide semiconductor material layer 130p. The oxide semiconductor material layer 130p may be subjected to heat treatment instead of the laser irradiating method. A temperature for laser irradiation or heat treatment may be from about 200° C. or to about 500° C., or from about 400° C. to about 500° C. or less. The capping layer 135 may serve as a buffer layer, for example, when the oxide semiconductor material layer 130p is changed from the amorphous state to a crystalline state by laser irradiation or heat treatment, thereby preventing a defect from being generated during the crystallization process.

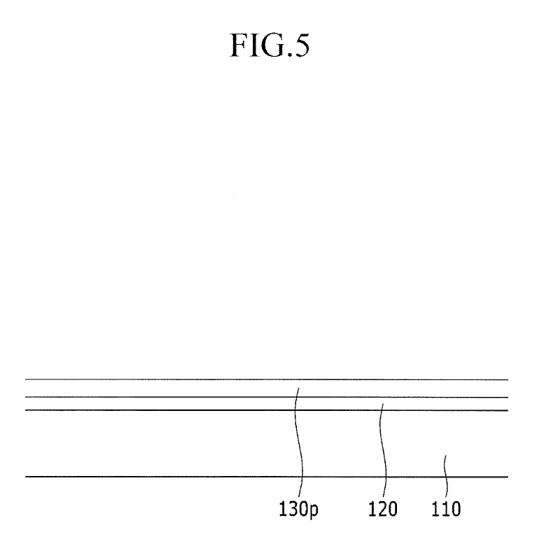

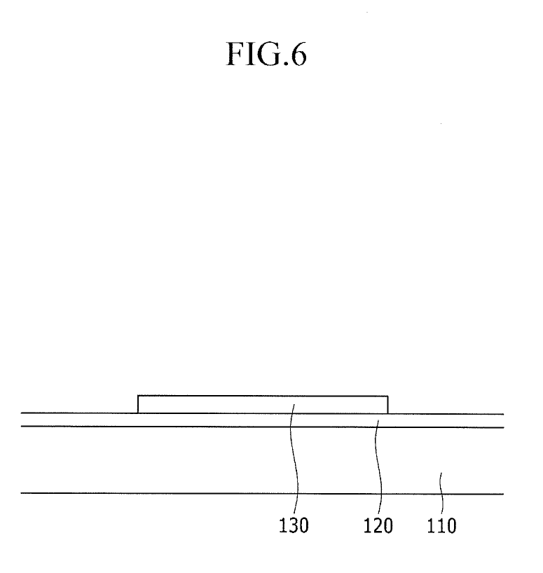

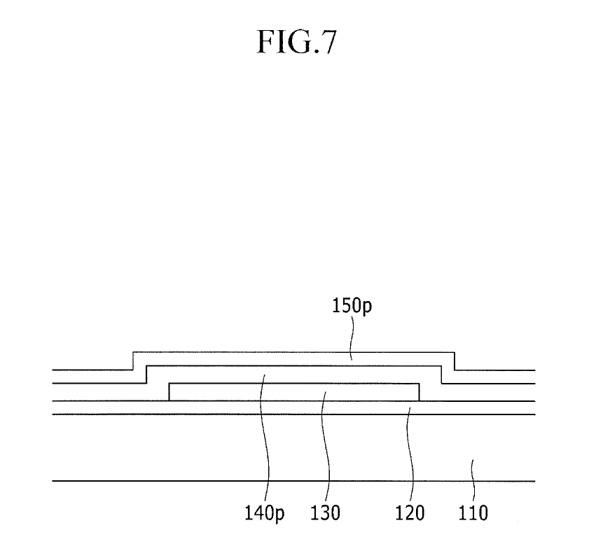

Referring to FIG. 5, the capping layer 135 serving as the buffer layer may be removed. Referring to FIG. 6, the oxide semiconductor material layer 130p may be etched by using a photosensitive film pattern as a mask, thereby forming an oxide semiconductor layer 130. Referring to FIG. 7, an insulating material layer 140p and a gate electrode material layer 150p may be coated to cover the oxide semiconductor layer 130. The insulating material layer 140p may be formed as a single layer including an insulating oxide such as silicon oxide (SiO₂), aluminum oxide (Al₂O₃), hafnium oxide (HfO₃), and/or yttrium oxide (Y₂O₃), and the insulating material layer 140p may also be formed as a multilayer of a double layer or more.

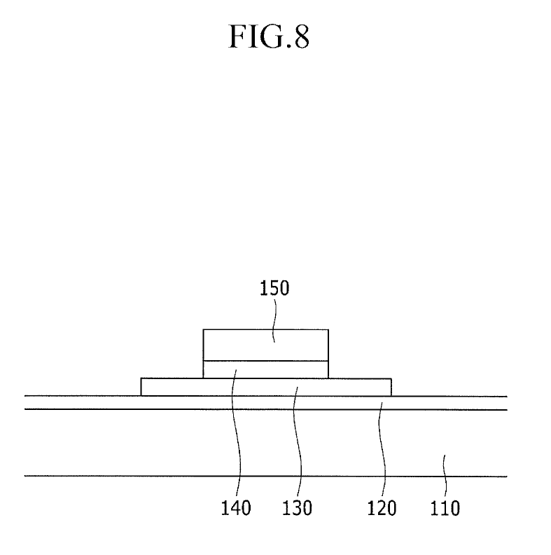

The gate electrode material layer 150p may include a conductive material such as a metal. Referring to FIG. 8, a gate electrode 150 may be formed by patterning the gate electrode material layer 150p, and a first insulating layer 140 may be formed by patterning the insulating material layer 140p by using, for example, the gate electrode 150 as an etching mask. The first insulating layer 140 and the gate electrode 150 may have the same planar pattern, and an edge boundary of the gate electrode 150 and an edge boundary of the first insulating layer 140 may substantially coincide with each other. A width of the gate electrode 150 may be smaller than a width of the oxide semiconductor layer 130.

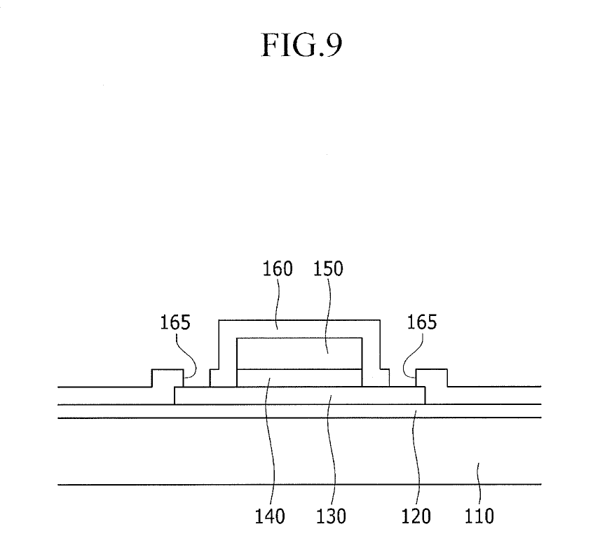

Referring to FIG. 9, an interlayer insulating layer 160 may be formed on the gate electrode 150, the oxide semiconductor layer 130, and the buffer layer 120. The interlayer insulating layer 160 may include an inorganic insulating material such as silicon nitride or silicon oxide, an organic insulating material, or the like. Next, a contact hole 165 exposing a part of the oxide semiconductor layer 130 may be formed by patterning the interlayer insulating layer 160. Thereafter, a thin film transistor, for example, which is illustrated in FIG. 1, may be formed by forming a source electrode 173 and a drain electrode 175 on the interlayer insulating layer 160. Each of the source electrode 173 and the drain electrode 175 may be formed to be electrically connected with the oxide semiconductor layer 130 through the contact hole 165.

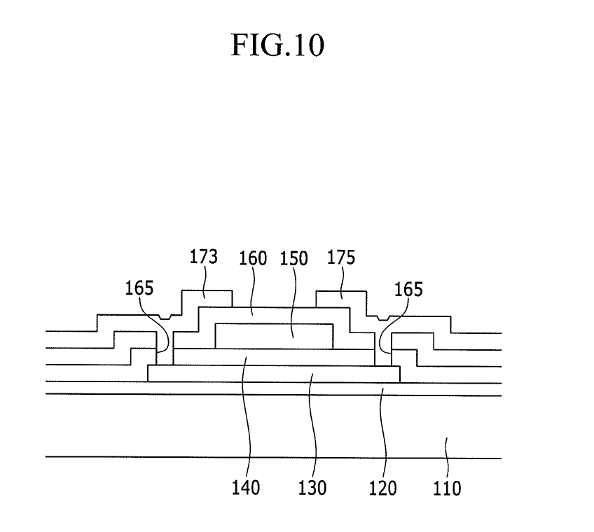

FIG. 10 illustrates a cross-sectional view illustrating a thin film transistor. Referring to FIG. 10, the embodiment may be different from the embodiment of FIG. 1 in that the first insulating layer 140 need not be arranged with the gate electrode 150. The first insulating layer 140 need not patterned just after the gate electrode 150 is formed during the manufacturing process, but may be patterned, for example, while the contact hole 165 is formed by patterning the second insulating layer 160. The contact hole 165 may be formed in the first insulating layer 140 and the second insulating layer 160. The contents described in FIG. 1 except for the difference described, for example, may be applied.

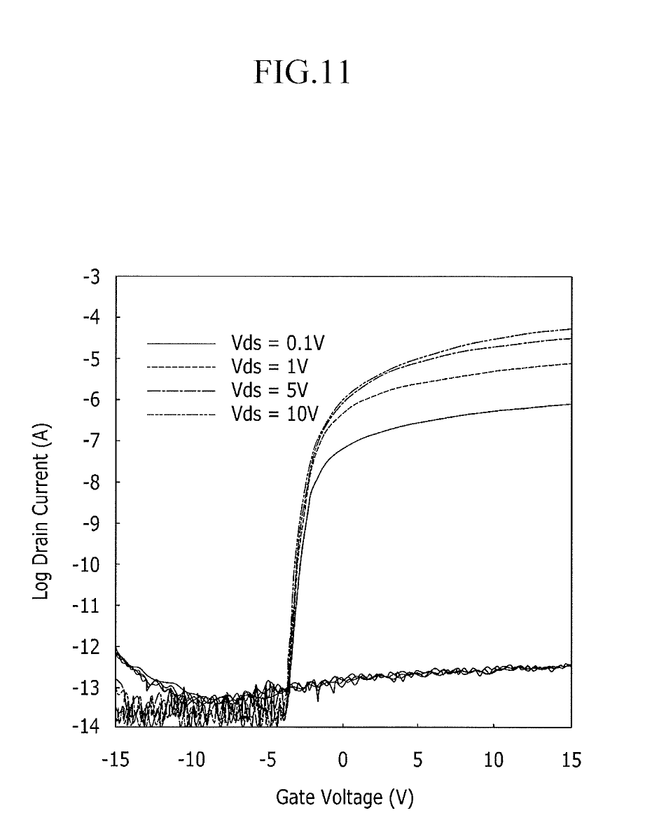

FIG. 11 illustrates a graph illustrating a characteristic of the thin film transistor manufactured according to a method described herein. A width and a length of a channel of the semiconductor layer was designed, for example, to be about 20 micrometers and about 10 micrometers, respectively, and a threshold voltage was about −3.6 volt. A characteristic of the manufactured thin film transistor was measured, and field effect mobility was about 16.12 cm²/(V·s), a threshold voltage was about −3.6 V, and a threshold slope (S.S) value after the threshold voltage was about 0.19 V/dec. Referring to FIG. 11, the thin film transistor manufactured according to a method described herein shows a characteristic as the thin film transistor that may serve as a switching element.

By way of summation and review, in a thin film transistor and a manufacturing method thereof, a chosen semiconductor is a factor that may help determine a characteristic of the thin film transistor. In such a semiconductor, amorphous silicon is frequently used, but there may be limit to manufacturing a high-performance thin film transistor due to low charge mobility. Further in the case of using polysilicon, while a high-performance thin film transistor may be generally manufactured given high charge mobility, there may be a limit to manufacturing a large-sized thin film transistor array panel due to high cost and low uniformity.

In contrast, the thin film transistor and manufacturing method thereof disclosed herein have the advantages of reducing a defect by crystallizing an oxide semiconductor layer at a low temperature. As disclosed herein, exemplary embodiments provide a thin film transistor using an oxide semiconductor, which has higher electron mobility and higher ON/OFF rate of current than amorphous silicon, and has lower cost and higher uniformity than polysilicon. Accordingly to exemplary embodiments, it is possible to improve reliability of a thin film transistor by crystallizing an oxide semiconductor layer through laser or heat treatment.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A thin film transistor, comprising:
a substrate;
an oxide semiconductor layer on the substrate;
a first insulating layer on the oxide semiconductor layer;
a gate electrode on the first insulating layer;
a second insulating layer on the gate electrode; and
a source electrode and a drain electrode on the second insulating layer and facing each other,
wherein each of the source electrode and the drain electrode is connected with the oxide semiconductor layer through a contact hole formed in the second insulating layer, and
the oxide semiconductor layer includes a polycrystalline semiconductor.

2. The thin film transistor as claimed in claim 1, wherein edge boundaries of the first insulating layer and the gate electrode coincide with each other.

3. The thin film transistor as claimed in claim 2, wherein the second insulating layer entirely covers a lateral side of the first insulating layer and a lateral side of the gate electrode.

4. The thin film transistor as claimed in claim 3, further comprising a buffer layer between the substrate and the oxide semiconductor layer.

5. The thin film transistor as claimed in claim 4, wherein one edge of each of the source electrode and the drain electrode overlaps with the gate electrode.

6. The thin film transistor as claimed in claim 1, wherein the contact hole is in the first insulating layer and the second insulating layer.

7. The thin film transistor as claimed in claim 6, further comprising a buffer layer between the substrate and the oxide semiconductor layer.

8. The thin film transistor as claimed in claim 7, wherein one edge of each of the source electrode and the drain electrode overlaps with the gate electrode.

9. A method of manufacturing a thin film transistor, the method comprising:
forming an oxide semiconductor layer on a substrate;
performing light irradiation or heat treatment on the oxide semiconductor layer;
forming an insulating material layer and a gate electrode material layer on the oxide semiconductor layer;
forming a gate electrode by patterning the gate electrode material layer;
forming an interlayer insulating layer on the gate electrode; and
forming a source electrode and a drain electrode on the interlayer insulating layer,
wherein each of the source electrode and the drain electrode is connected with the oxide semiconductor layer through a contact hole in the interlayer insulating layer, and
the oxide semiconductor layer includes a polycrystalline semiconductor.

10. The manufacturing method of a thin film transistor as claimed in claim 9, further comprising:
forming a capping layer on the oxide semiconductor layer before the performing of light irradiation or heat treatment on the oxide semiconductor layer; and
removing the capping layer after the performing of light irradiation or heat treatment on the oxide semiconductor layer.

11. The manufacturing method of a thin film transistor as claimed in claim 10, wherein a process temperature for performing light irradiation or heat treatment on the oxide semiconductor layer is about 400° C. or more and about 500° C. or less.

12. The manufacturing method of a thin film transistor as claimed in claim 11, further comprising forming an insulating layer by patterning the insulating material layer by using the gate electrode as a mask.

13. The manufacturing method of a thin film transistor as claimed in claim 12, wherein the interlayer insulating layer is formed to entirely cover a side of the insulating layer and a side of the gate electrode.

14. The manufacturing method of a thin film transistor as claimed in claim 13, further comprising forming a buffer layer between the substrate and the oxide semiconductor layer.

15. The manufacturing method of a thin film transistor as claimed in claim 14, wherein one edge of each of the source electrode and the drain electrode is formed to overlap with the gate electrode.

16. The manufacturing method of a thin film transistor as claimed in claim 11, further comprising forming the contact hole in the insulating material layer and the interlayer insulating layer.

17. The manufacturing method of a thin film transistor as claimed in claim 16, further comprising forming a buffer layer between the substrate and the oxide semiconductor layer.

18. The manufacturing method of a thin film transistor as claimed in claim 17, wherein one edge of each of the source electrode and the drain electrode is formed to overlap with the gate electrode.
